(19) United States
(12) Patent Application Publication
(10) Pub. No.: US 2012/0309178 A1
(43) Pub. Date: Dec. 6, 2012

(54) METHOD OF MANUFACTURING FREE-STANDING SUBSTRATE

(75) Inventors: JunSung CHOI, ChungCheongNam-Do (KR); Hyun Jong Park, ChungCheongNam-Do (KR); Cheolmin Park, ChungCheongNam-Do (KR); Junyoung Bae, ChungCheongNam-Do (KR); Seonghwan Shin, ChungCheongNam-Do (KR); Dongwook Lee, ChungCheongNam-Do (KR); Wonjo Lee, ChungCheongNam-Do (KR); Youshin Han, ChungCheongNam-Do (KR)

(73) Assignee: SAMSUNG CORNING PRECISION MATERIALS CO., LTD.

(21) Appl. No.: 13/486,418

(22) Filed: Jun. 1, 2012

(30) Foreign Application Priority Data
Jun. 2, 2011 (KR) 10-2011-0053276

(51) Int. Cl. C23C 14/48; H01L 21/20

(52) U.S. Cl. 438/493; 427/523; 257/E21.09

(57) ABSTRACT

A method of manufacturing a free-standing substrate includes the steps of growing a first thin film on a heterogeneous substrate, forming an ion implantation layer in the first thin film by implanting ions into the first thin film, dividing the first thin film into an upper thin film and a lower thin film with respect to the ion implantation layer, and growing a second thin film on the upper thin film. The free-standing substrate is manufactured without warping or cracking. No additional processes, such as a laser separation process, for separating the free-standing substrate from the heterogeneous substrate are required.

### CROSS REFERENCE TO RELATED APPLICATION

The present application claims priority from Korean Patent Application Number 10-2011-0053276 filed on Jun. 2, 2011, the entire contents of which application are incorporated herein for all purposes by this reference.

### BACKGROUND OF THE INVENTION

1. Field of the Invention

The present invention relates to a method of manufacturing a free-standing substrate, and more particularly, to a method of manufacturing a free-standing substrate, by which the free-standing substrate can be manufactured without warping or cracking.

2. Description of Related Art

Recently, studies on the use of nitride semiconductors, such as aluminum nitride (AlN), gallium nitride (GaN) and indium nitride (InN), as materials for the manufacture of cutting-edge devices, such as light-emitting diodes (LEDs) and laser diodes (LDs), are actively underway.

In particular, GaN can generate light in the range from ultraviolet (UV) radiation to blue light, since it has a very wide direct transition energy band gap. GaN is a next-generation optoelectronic material that is used as a key material for blue LDs, which are regarded as the next-generation digital versatile disc (DVD) light source, white LEDs, which are expected to replace other light sources in the illumination market, high-temperature and high-power electrical devices, and the like.

Since there are no practical homogenous substrates for GaN, a GaN thin film is produced by forming a thin film on a heterogeneous substrate (made of, for example, sapphire, silicon carbide (SiC), or silicon (Si)) using a variety of methods, such as metal-organic chemical vapor deposition (MOCVD) and hydride vapor phase epitaxy (HVPE).

However, such methods have problems in that a GaN thin film, especially when grown on a sapphire substrate, is vulnerable to warping, cracking, and the like, owing to the lattice constant difference (13.8%) and the thermal expansion coefficient difference (25.5%) between the substrate and the thin film.

Since all of these defects occur due to lattice mismatch and thermal expansion coefficient mismatch owing to the use of the heterogeneous substrate, such as a sapphire substrate or a SiC substrate, they can be overcome by growing the GaN thin film using a homogeneous substrate, i.e. a GaN substrate.

In the related art, a free-standing GaN substrate was produced by growing a GaN film to a thickness of 300 μm or greater on a sapphire substrate, followed by separating the GaN film from the sapphire substrate. Therefore, the problem is that an additional process of separating the grown free-standing substrate from the heterogeneous substrate is required.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method of manufacturing a free-standing substrate, by which the free-standing substrate can be manufactured without warping or cracking.

In an aspect of the present invention, provided is a method of manufacturing a free-standing substrate that includes the following steps of: growing a first thin film on a heterogeneous substrate;

forming an ion implantation layer in the first thin film by implanting ions into the first thin film; dividing the first thin film into an upper thin film and a lower thin film with respect to the ion implantation layer; and growing a second thin film on the upper thin film.

In an exemplary embodiment of the invention, the thin films may be gallium nitride (GaN) thin films.

In an exemplary embodiment of the invention, the heterogeneous substrate may be made of one selected from the group consisting of sapphire, silicon carbide (SiC), silicon (Si) and gallium arsenide (GaAs).

In an exemplary embodiment of the invention, the step of growing the first thin film may grow the first thin film to a thickness of 5 μm or greater.

In an exemplary embodiment of the invention, the ions in the step of forming the ion implantation layer may be hydrogen (H) ion.

In an exemplary embodiment of the invention, the step of forming the ion implantation layer may implant the ions to a dept ranging from 100 nm to 2 μm from a surface of the first thin film. pin In an exemplary embodiment of the invention, the step of growing the second thin film may be performed at a temperature raised to 1000° C. or higher.

According to embodiments of the invention, it is possible to manufacture a free-standing substrate by dividing a thin film, which is grown on a heterogeneous substrate, into upper and lower thin films and then growing another film on the upper thin film, so that the free-standing substrate can be manufactured without warping or cracking.

In addition, according to embodiments of the invention, it is possible to manufacture a free-standing substrate without an additional process, such as a laser separation process, for separating the free-standing substrate from the heterogeneous substrate.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a flowchart showing a method of manufacturing a free-standing substrate according to an exemplary embodiment of the invention; and

FIG. 2 is a conceptual view schematically showing the method shown in FIG. 1.

### DETAILED DESCRIPTION OF THE INVENTION

Reference will now be made in detail to a method of manufacturing a free-standing substrate according to the invention, embodiments of which are illustrated in the accompanying drawings and described below.

In the following description of the present invention, detailed descriptions of known functions and components incorporated herein will be omitted when they may make the subject matter of the present invention unclear.

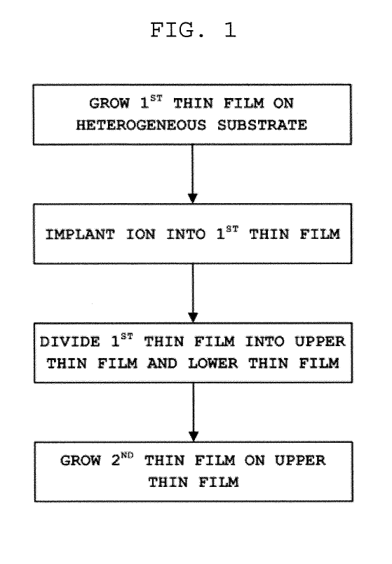

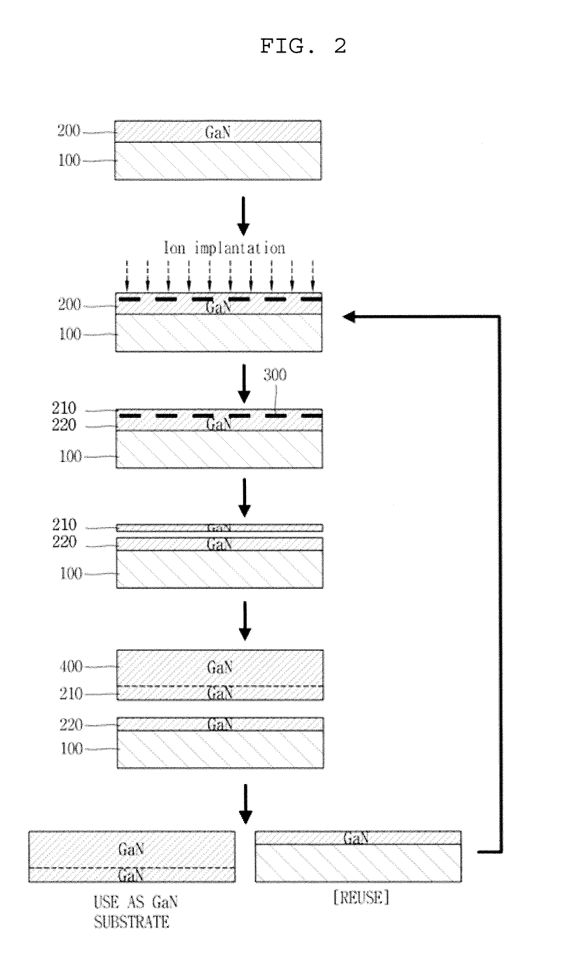

FIG. 1 is a flowchart showing a method of manufacturing a free-standing substrate according to an exemplary embodiment of the invention, and FIG. 2 is a conceptual view schematically showing the method shown in FIG. 1.

Referring to FIG. 1 and FIG. 2, the method of manufacturing a free-standing substrate according to an exemplary embodiment of the invention includes the steps of: growing a first thin film on a heterogeneous substrate (first step), forming an ion implantation layer by implanting ions into the first thin film, which is grown in the first step (second step), dividing the first thin film into an upper thin film and a lower thin film with respect to the ion implantation layer (third step), and growing a second thin film again on the upper thin film (fourth step).

First, a heterogeneous substrate 100 is loaded into a growth chamber, and then a source, which is required for thin film growth, is supplied into the growth chamber, so that a first thin film 200 made of the same material as the free-standing substrate 400 that is intended to be manufactured is grown on the heterogeneous substrate 100 (first step).

Here, the heterogeneous substrate 100 may be made of one selected from among silicon carbide (SiC), silicon (Si) and gallium arsenide (GaAs) , and the thin film 200 that is grown may be a thin film of gallium nitride (GaN).

The first thin film 200 may be grown using a variety of methods, such as metal-organic chemical vapor deposition (MOCVD) and hydride vapor phase epitaxy (HVPE), which can be used to grow a thin film.

It is preferred that the first thin film 200 be grown to a thickness of 5 μm or greater.

The heterogeneous substrate 100 on which the first thin film 200 is grown in the first step is taken out of the growth chamber, and then ions are implanted into the first thin film 200 using an ion implanter, thereby forming an ion implantation layer 300 (second layer).

Although the ions may be selected from a variety of ions, such as hydrogen (H), boron (B), carbon (C), oxygen (O) and fluorine (F) ions, the H ions are preferably used.

The ions may be implanted in such a fashion that the ion implantation layer 300, i.e. an ion implantation peak area, is formed at a depth ranging from 100 nm to 2 μm from the surface of the thin film.

Afterwards, the heterogeneous substrate 100 is loaded into the growth chamber, and then the temperature is raised to a predetermined temperature at which a second thin film is intended to grow in the subsequent fourth step. While the temperature is being raised, the ions start to expand. Due to this expansion of the ions, the first thin film is divided into an upper thin film 210 and a lower thin film 220 with respect to the ion implantation layer 300, i.e. the ion implantation peak area. In particular, when the implanted ions are H ions, the first thin film is divided into the upper thin film and the lower thin film with respect to the ion implantation peak area at a temperature ranging from 400° C. to 500° C. (third step).

When the temperature is raised to, for example, 1000° C. or higher, the second thin film starts to grow (fourth step).

The second thin film grows into a film of several hundred micrometers without warping or cracking.

Since the second thin film 400 is grown on the divided upper thin film 210, which is made of the same material as the second thin film 400, neither lattice mismatch nor thermal expansion coefficient mismatch occurs between the first thin film and the second thin film. Therefore, the second thin film 400 can grow to a thickness of several hundred micrometers or greater without warping or cracking.

The resultant structure including the upper thin film 210 and the second thin film 400, which is grown to several hundred micrometers, will be used as a free-standing substrate after being cooled.

In addition, the lower structure including the heterogeneous substrate 100 and the lower thin film 220, which is below the ion implantation peak area, is already separated due to the expansion of the implanted ions during the process of manufacturing the free-standing substrate. Therefore, unlike the related art, no additional processes, such as a laser separation process, for separating the free-standing substrate are required.

In addition, the lower structure including the heterogeneous substrate 100 and the lower thin film 220 grown on the heterogeneous substrate 100, which is below the ion implantation peak area, can be reused in the manufacture of a free-standing substrate by being passed through the step of ion implantation. That is, the first to fourth steps are repeated n times (where n is a natural number that is equal to or greater than 2), and the lower thin film, produced in the (i−1) cycle, is used as a first thin film in the i^{th} cycle (where i is a natural number and 2≦i≦n).

Here, when the thickness of the thin film (lower thin film) grown on the heterogeneous substrate is insufficient for implanting ions thereinto in the step of ion implantation, the thin film can be reused after being passed through a step of thin film growth. That is, when the first to fourth steps are repeated n times (where n is a natural number that is equal to or greater than 2), a combination including the lower thin film, which is produced in the (i−1)^{th} cycle, and a supplementary thin film, which is supplementarily grown on the lower thin film, is used as a first film in the i^{th} cycle.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A method of manufacturing a free-standing substrate, comprising:
a first step of growing a first thin film on a heterogeneous substrate;
a second step of forming an ion implantation layer in the first thin film by implanting ions into the first thin film;
a third step of dividing the first thin film into an upper thin film and a lower thin film with respect to the ion implantation layer; and
a fourth step of growing a second thin film on the upper thin film.

2. The method of claim 1, wherein the first thin film and the second thin film are made of a homogeneous material.

3. The method of claim 1, wherein the first thin film and the second thin film are gallium nitride (GaN) thin films.

4. The method of claim 1, wherein the heterogeneous substrate is made of one selected from the group consisting of sapphire, silicon carbide (SiC), silicon (Si) and gallium arsenide (GaAs).

5. The method of claim 1, wherein the first thin film is grown to a thickness of 5 μm or greater, and the second thin film is grown to a thickness of several hundred micrometers or greater.

6. The method of claim 1, wherein the ions are hydrogen (H) ions.

7. The method of claim 1, wherein
the first thin film is divided into the upper thin film and the lower thin film at a first temperature, and
the second thin film is grown at a second temperature that is higher than the first temperature.

8. The method of claim 7, wherein the second temperature is 1000° C. or higher.

9. The method of claim 7, wherein the first thin film is divided while a temperature is being raised to the second temperature at which the second thin film is grown.

10. The method of claim 1, wherein
the first to fourth steps are repeated n times, where n is a natural number of 2 or greater, and
the first thin film in an i^{th} cycle comprises the lower thin film in an (i−1)^{th} cycle, where i is a natural number and 2≦i≦n.

11. The method of claim 10, wherein
the first thin film in the i^{th} cycle is a combination that includes the lower thin film in the (i−1)th cycle, and a supplementary thin film supplementarily grown on the lower thin film in the (i−1)^{th} cycle.
